(19) United States
(12) Patent Application Publication
(10) Pub. No.: US 2023/0117294 A1
(43) Pub. Date: Apr. 20, 2023

(54) ANTIMICROBIAL PLASTIC FILM AND WINDING COATING METHOD THEREOF

(71) Applicant: Shuihe CHEN, Hong Kong (CN)

(72) Inventor: Shuihe CHEN, Hong Kong (CN)

(21) Appl. No.: 17/670,710

(22) Filed: Feb. 14, 2022

(30) Foreign Application Priority Data
Oct. 19, 2021 (CN) 202111212928.2

(51) Int. Cl. A01N 25/10; A01N 59/16; A01N 59/00; C23C 14/34; C23C 14/06; C23C 14/20; C23C 14/02

(52) U.S. Cl. CPC A01N 25/10; A01N 59/16; A01N 59/00; C23C 14/3414; C23C 14/0682; C23C 14/0635; C23C 14/205; C23C 14/024

(57) ABSTRACT

The present invention relates to an antimicrobial plastic film and a winding coating method, the antimicrobial plastic film includes a plastic film main part, wherein a surface of said plastic film main part is coated with an antimicrobial coating, the antimicrobial coating includes a bonding layer, a carrier layer, a first antimicrobial layer and a second antimicrobial layer, the winding coating method includes the steps of vacuum treatment , applying a bonding layer, applying a carrier layer, applying a first antimicrobial layer, and applying a second antimicrobial layer

### TECHNICAL FIELD

The present invention relates to the technical field of vacuum coating and plastic film materials, in particular to an antimicrobial plastic film and a winding coating method thereof.

### BACKGROUND ART

With social development, stable industrial growth and the perfection of production technologies, production level has increased. With high-tech means being widely used, their application field are widened. With economic globalization, market internationalization, and development and progress in material technologies, people's material life levels become so higher and higher as to require the higher and higher materials performance. As common materials for daily use, plastic films are widely used, especially in the fields of medical quarantine, daily necessities, diet or packaging, so they are often used as disposable materials to make protective articles such as protective clothing, gloves, protective films and preservative films, having huge function. However, besides wide use, the traditional films usually have very simple function, for example, they do not have antimicrobial function, and the manufactured articles do not have antimicrobial function, providing poor protection and low safety for users.

### SUMMARY

The main objective of the present invention is to overcome the deficiencies in the prior art, providing an antimicrobial plastic film and a winding coating method thereof, to solve the problems of traditional plastic films such as single function, unsanitary, non-environmental friendliness, poor protection and low safety.

To achieve the above objectives, the technical embodiment provided by the present invention is: an antimicrobial plastic film comprising a plastic film main part, the surface of the plastic film main part is coated with an antimicrobial coating, the antimicrobial coating includes a bonding layer, a carrier layer, a first antimicrobial layer and a second antimicrobial layer.

As a further embodiment of the present invention, the structural materials of the plastic film main part 1 include PET, TPU, EVA, PU, PP, PVC, PE, PO, ABS, PC, POM, PA, TPE and silica gel.

As a further embodiment of the present invention, the antimicrobial coating completely covers the outer surface of the plastic film main part.

As a further embodiment of the present invention, the antimicrobial coating completely covers the inner surface of the plastic film main part.

As a further embodiment of the present invention, the bonding layer includes a layer made from Si.

As a further embodiment of the present invention, the carrier layer includes a layer made from Si and TiC.

As a further embodiment of the present invention, the first antimicrobial layer includes a layer made from Si, TiC and Ag.

As a further embodiment of the present invention, the second antimicrobial layer includes a layer made from Si, TiC, first Ag and second Ag.

The present invention further provides a winding coating method of an antimicrobial plastic film, comprising the following steps:

(1) pretreatment: installing reels and a film on a shelf, putting them into a vacuum chamber, then starting to wind the film on one reel and unwind the film off another reel, performing corona treatment;

(2) vacuum treatment: evacuating the vacuum chamber to 1×10-3 Pa;

(3) applying a bonding layer: turning on the mid-frequency power supply and adjusting it to 30-40V with a duty ratio of 20%-30%, and passing argon until the vacuum degree reaches 2.0×10-2 Pa, starting to sputter on P-type Si target, with the current density of the P-type Si target being 6 A and the chamber temperature adjusted to 40° C., and then staring to reel the film at the linear speed of the film being 0.1-0.3 m/s, sputtering the P-type Si target towards the moving-ahead direction of the film to form a Si bonding film on the surface of the film, the film coated with the Si bonding layer continuing to move ahead into the next coating process;

(4) applying a carrier layer: concurrently sputtering the P-type Si target and a TiC target by using mid-frequency power supply, with the current density of the TiC target being 6 A, and the chamber temperature of 40° C., according to the moving-ahead direction of the film, arranging the P-type Si target and the TiC target in sequence and concurrently sputtering them to form a carrier layer containing Si and TiC on the surface of the film, the film coated with the carrier layer containing Si and TiC continuing to move ahead into the next coating process;

(5) applying a first antimicrobial layer: holding the P-type Si target and the TiC target, meanwhile starting a first Ag target, by using DC power supply by using DC power supply with the current density of the first Ag target being 0.4 A, and the chamber temperature of 40° C., according to the moving-ahead direction of the film, arranging the P-type Si target, the TiC target and the first Ag target in sequence and concurrently sputtering them to form a first antimicrobial layer containing Si, TiC and Ag on the surface of the film, the film coated with the first antimicrobial layer containing Si, TiC and Ag continuing to move ahead into the next coating process;

(6) applying a second antimicrobial layer: another set of P-type Si target, TiC target and first Ag target start to sputter with same condition as (5) process, meanwhile starting a second Ag target, with the current density of the second Ag target being 0.4 A, and the chamber temperature of 40° C., according to the moving-ahead direction of the film, arranging the P-type Si target, the TiC target, the first Ag target and the second Ag target in sequence and concurrently sputtering them to form a second antimicrobial layer containing Si, TiC, first Ag and second Ag on the surface of the film, winding the other end of the film on the second reel at the same time;

(7) completing coating: First turning off all the P-type Si target and the TiC target, then turning off the first Ag target and the second Ag target, then cutting off all the gases, and stopping the rolling mechanism, after chamber cooling down by itself for 5-10 minutes, ventilating the vacuum chamber to atmospheric pressure section by section, and taking out the workpiece to complete coating.

In summary, by using the above technical solution, an antimicrobial coating is applied on a plastic film, without chemical treatment required for the whole process and no damage on the surface of the plastic film during applying coatings. As two sets of P-type Si target, TiC target and first Ag target are used for applying an antimicrobial coating, the main component of the coating contains a large number of C atoms, and has a good bonding force with the Si atoms in the coating, in addition, Ag target sputtering makes Ag atoms having sterilization effect evenly distributed in the plastic film to form an antimicrobial coating having sterilization effect. Furthermore, During the coating process, the plastic film moves ahead at an uniform speed, so that the sputtering process makes the coating more uniformly formed, and the plastic film passes through different targets to produce a composite coating, avoiding local high temperature from damaging the plastic film. Si atoms can not only compensate the coating defects of TiC and raise the hardness of TiC, but also reduce porosity, lipophilicity and conductivity, and abate fingerprint effect. The antimicrobial plastic film is healthy and environmentally friendly, with relative convenience to manufacture, not only retaining various characteristics and appearance of the original film, but also having sterilization effect, so as to achieve the beneficial effects of high protection and safety for users in use.

### BRIEF DESCRIPTION OF THE DRAWINGS

FIG. 1 is a diagrammatic cross-section of the antimicrobial plastic film of the antimicrobial plastic film and the winding coating method thereof according the present invention.

FIG. 2 is a diagrammatic cross-section of the antimicrobial coating of the antimicrobial plastic film and the winding coating method thereof according the present invention.

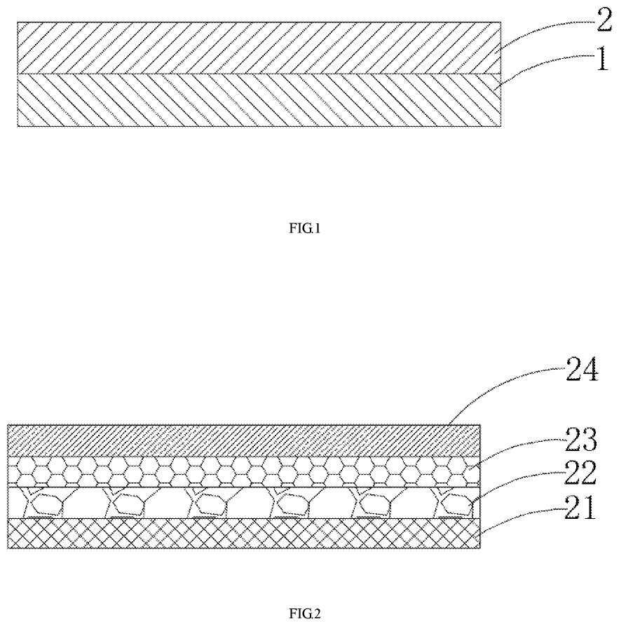

Element description in the figures: 1—plastic film main part; 2—antimicrobial coating; 21—bonding layer; 22—carrier layer; 23—first antimicrobial layer; 24—second antimicrobial layer.

### DETAILED DESCRIPTION OF THE EMBODIMENTS

The technical solutions in the embodiments of the present invention will be clearly and completely described as follows in combination with the drawings in the examples of the present invention, but obviously, the described examples are only a part of the embodiments of the present invention, rather than all the embodiments. Based on the examples of the present invention, all other examples obtained by a person skilled in the art without creative efforts shall fall within the protection scope of the present invention.

An antimicrobial plastic film includes an plastic film main part 1, the surface of which is coated with an antimicrobial coating 2. The antimicrobial coating 2 includes a bonding layer 21, a carrier layer 22, a first antimicrobial layer 23 and a second antimicrobial layer 24.

Preferably, in the above-mentioned antimicrobial plastic film, the structural materials of the plastic film main part 1 include: PET, TPU, EVA, PU, PP, PVC, PE, PO, ABS, PC, POM, PA, TPE and silica gel.

Preferably, in the above-mentioned antimicrobial plastic film, the antimicrobial coating 2 completely covers the outer surface of the plastic film main part 1.

Preferably, in the above-mentioned antimicrobial plastic film, the antimicrobial coating 2 completely covers the inner surface of the plastic film main part 1.

Preferably, in the above-mentioned antimicrobial plastic film, the bonding layer 21 includes a layer made from Si.

Preferably, in the above-mentioned antimicrobial plastic film, the carrier layer 22 includes a layer made from Si and TiC. Due to porosity, TiC has very strong free energy and high lipophilicity on its surface, so the produced film has remarkable fingerprint effect. Si atoms can not only compensate the coating defects of TiC and raise the hardness of TiC, but also reduce porosity, lipophilicity and conductivity, and abate fingerprint effect, so they are beneficial to fix the nano-Ag particles on the coating during the follow-up process.

Preferably, in the above-mentioned antimicrobial plastic film, the first antimicrobial layer 23 includes a layer made from Si, TiC and Ag, where Si and TiC fix Ag ions on the antimicrobial coating 2.

Preferably, in the above-mentioned antimicrobial plastic film, the second antimicrobial layer 24 includes a layer made from Si, TiC, first Ag and second Ag.

The present invention further provides a winding coating method of an antimicrobial plastic film, comprising the following steps:

(1) pretreatment: installing reels and a film on a shelf, putting them into a vacuum chamber, then starting to wind the film on one reel and unwind the film off another reel, performing corona treatment;

(2) vacuum treatment: evacuating the vacuum chamber to 1×10-3 Pa;

(3) applying a bonding layer: turning on the mid-frequency power supply and adjusting it to 30-40 V with a duty ratio of 20%-30%, and passing argon until the vacuum degree reaches 2.0×10-2 Pa, starting to sputter on P-type Si target, with the current density of the P-type Si target being 6 A and the chamber temperature adjusted to 40° C., and then staring to reel the film at the linear speed of the film being 0.1-0.3 m/s, sputtering the P-type Si target towards the moving-ahead direction of the film to form a Si bonding film on the surface of the film, the film coated with the Si bonding layer continuing to move ahead into the next coating process;

(4) applying a carrier layer: concurrently sputtering the P-type Si target and a TiC target by using mid-frequency power supply, with the current density of the TiC target being 6A, and the chamber temperature of 40° C., according to the moving-ahead direction of the film, arranging the P-type Si target and the TiC target in sequence and concurrently sputtering them to form a carrier layer containing Si and TiC on the surface of the film, the film coated with the carrier layer containing Si and TiC continuing to move ahead into the next coating process;

(5) applying a first antimicrobial layer: holding the P-type Si target and the TiC target, meanwhile starting a first Ag target, by using DC power supply with the current density of the first Ag target being 0.4 A, and the chamber temperature of 40° C., according to the moving-ahead direction of the film, arranging the P-type Si target, the TiC target and the first Ag target in sequence and concurrently sputtering them to form a first antimicrobial layer containing Si, TiC and Ag on the surface of the film, the film coated with the first antimicrobial layer containing Si, TiC and Ag continuing to move ahead into the next coating process;

(6) applying a second antimicrobial layer: another set of P-type Si target, TiC target and first Ag target start to sputter with same condition as (5) process, meanwhile starting a second Ag target, with the current density of the second Ag target being 0.4 A, and the chamber temperature of 40° C., according to the moving-ahead direction of the film, arranging the P-type Si target, the TiC target, the first Ag target and the second Ag target in sequence and concurrently sputtering them to form a second antimicrobial layer containing Si, TiC, first Ag and second Ag on the surface of the film, winding the other end of the film on the second reel at the same time;

(7) completing coating: first turning off the P-type Si target and the TiC target, then turning off the first Ag target and the second Ag target, then cutting off all the gases, and stopping the rolling mechansim, after chamber cooling down by itself for 5-10 minutes, ventilating the vacuum chamber to atmospheric pressure section by section, and taking out the workpiece to complete coating.

### EXAMPLE 1

A winding coating method of an antimicrobial plastic film, comprising the following steps:

(1) pretreatment: installing reels and a film on a shelf, putting them into a vacuum chamber, then starting to wind the film on one reel and unwind the film off another reel, performing corona treatment;

(2) vacuum treatment: evacuating the vacuum chamber to 1×10-3 Pa;

(3) applying a bonding layer: turning on the mid-frequency power supply and adjusting it to 30V with a duty ratio of 20%-30%, and passing argon until the vacuum degree reaches 2.0×10-2 Pa, starting to sputter on P-type Si target, with the current density of the P-type Si target being 6 A and the chamber temperature adjusted to 40° C., and then staring to reel the film at the linear speed of the film being 0.1-0.3 m/s, sputtering the P-type Si target towards the moving-ahead direction of the film to form a Si bonding film on the surface of the film, the film coated with the Si bonding layer continuing to move ahead into the next coating process;

(4) applying a carrier layer: concurrently sputtering the P-type Si target and a TiC target by using mid-frequency power supply, with the current density of the TiC target being 6 A, and the chamber temperature of 40° C., according to the moving-ahead direction of the film, arranging the P-type Si target and the TiC target in sequence and concurrently sputtering them to form a carrier layer containing Si and TiC on the surface of the film, the film coated with the carrier layer containing Si and TiC continuing to move ahead into the next coating process;

(5) applying a first antimicrobial layer: holding the P-type Si target and the TiC target, meanwhile starting a first Ag target, by using DC power supply with the current density of the first Ag target being 0.4 A, and the chamber temperature of 40° C., according to the moving-ahead direction of the film, arranging the P-type Si target, the TiC target and the first Ag target in sequence and concurrently sputtering them to form a first antimicrobial layer containing Si, TiC and Ag on the surface of the film, the film coated with the first antimicrobial layer containing Si, TiC and Ag continuing to move ahead into the next coating process;

(6) applying a second antimicrobial layer: another set of P-type Si target, TiC target and first Ag target start to sputter with same condition as (5) process, meanwhile starting a second Ag target, with the current density of the second Ag target being 0.4 A, and the chamber temperature of 40° C., according to the moving-ahead direction of the film, arranging the P-type Si target, the TiC target, the first Ag target and the second Ag target in sequence and concurrently sputtering them to form a second antimicrobial layer containing Si, TiC, first Ag and second Ag on the surface of the film, winding the other end of the film on the second reel at the same time;

(7) completing coating: first turning off the P-type Si target and the TiC target, then turning off the first Ag target and the second Ag target, then cutting off all the gases, and stopping the rolling mechansim, after chamber cooling down by itself for 5 minutes, ventilating the vacuum chamber to atmospheric pressure section by section, and taking out the workpiece to complete coating.

### EXAMPLE 2

A winding coating method of an antimicrobial plastic film, comprising the following steps:

(1) pretreatment: installing reels and a film on a shelf, putting them into a vacuum chamber, then starting to wind the film on one reel and unwind the film off another reel, performing corona treatment;

(2) vacuum treatment: evacuating the vacuum chamber to 1×10-3 Pa;

(3) applying a bonding layer: turning on the mid-frequency power supply and adjusting it to 35V with a duty ratio of 20%-30%, and passing argon until the vacuum degree reaches 2.0×10-2 Pa, starting to sputter on P-type Si target, with the current density of the P-type Si target being 6 A and the chamber temperature adjusted to 40° C., and then staring to reel the film at the linear speed of the film being 0.1-0.3 m/s, sputtering the P-type Si target towards the moving-ahead direction of the film to form a Si bonding film on the surface of the film, the film coated with the Si bonding layer continuing to move ahead into the next coating process;

(4) applying a carrier layer: concurrently sputtering the P-type Si target and a TiC target by using mid-frequency power supply, with the current density of the TiC target being 6 A, and the chamber temperature of 40° C., according to the moving-ahead direction of the film, arranging the P-type Si target and the TiC target in sequence and concurrently sputtering them to form a carrier layer containing Si and TiC on the surface of the film, the film coated with the carrier layer containing Si and TiC continuing to move ahead into the next coating process;

(5) applying a first antimicrobial layer: holding the P-type Si target and the TiC target, meanwhile starting a first Ag target, by using DC power supply with the current density of the first Ag target being 0.4 A, and the chamber temperature of 40° C., according to the moving-ahead direction of the film, arranging the P-type Si target, the TiC target and the first Ag target in sequence and concurrently sputtering them to form a first antimicrobial layer containing Si, TiC and Ag on the surface of the film, the film coated with the first antimicrobial layer containing Si, TiC and Ag continuing to move ahead into the next coating process;

(6) applying a second antimicrobial layer: another set of P-type Si target, TiC target and first Ag target start to sputter with same condition as (5) process, meanwhile starting a second Ag target, with the current density of the second Ag target being 0.4 A, and the chamber temperature of 40° C., according to the moving-ahead direction of the film, arranging the P-type Si target, the TiC target, the first Ag target and the second Ag target in sequence and concurrently sputtering them to form a second antimicrobial layer containing Si, TiC, first Ag and second Ag on the surface of the film, winding the other end of the film on the second reel at the same time;

(7) completing coating: first turning off the P-type Si target and the TiC target, then turning off the first Ag target and the second Ag target, then cutting off all the gases, and stopping the rolling mechansim, after chamber cooling down by itself for 8 minutes, ventilating the vacuum chamber to atmospheric pressure section by section, and taking out the workpiece to complete coating.

### EXAMPLE 3

A winding coating method of an antimicrobial plastic film, comprising the following steps:

(1) pretreatment: installing reels and a film on a shelf, putting them into a vacuum chamber, then starting to wind the film on one reel and unwind the film off another reel, performing corona treatment;

(2) vacuum treatment: evacuating the vacuum chamber to 1×10-3 Pa;

(3) applying a bonding layer: turning on the mid-frequency power supply and adjusting it to 40V with a duty ratio of 20%-30%, and passing argon until the vacuum degree reaches 2.0×10-2 Pa, starting to sputter on P-type Si target, with the current density of the P-type Si target being 6 A and the chamber temperature adjusted to 40° C., and then staring to reel the film at the linear speed of the film being 0.1-0.3 m/s, sputtering the P-type Si target towards the moving-ahead direction of the film to form a Si bonding film on the surface of the film, the film coated with the Si bonding layer continuing to move ahead into the next coating process;

(4) applying a carrier layer: concurrently sputtering the P-type Si target and a TiC target by using mid-frequency power supply, with the current density of the TiC target being 6 A, and the chamber temperature of 40° C., according to the moving-ahead direction of the film, arranging the P-type Si target and the TiC target in sequence and concurrently sputtering them to form a carrier layer containing Si and TiC on the surface of the film, the film coated with the carrier layer containing Si and TiC continuing to move ahead into the next coating process;

(5) applying a first antimicrobial layer: holding the P-type Si target and the TiC target, meanwhile starting a first Ag target, by using DC power supply with the current density of the first Ag target being 0.4 A, and the chamber temperature of 40° C., according to the moving-ahead direction of the film, arranging the P-type Si target, the TiC target and the first Ag target in sequence and concurrently sputtering them to form a first antimicrobial layer containing Si, TiC and Ag on the surface of the film, the film coated with the first antimicrobial layer containing Si, TiC and Ag continuing to move ahead into the next coating process;

(6) applying a second antimicrobial layer: another set of P-type Si target, TiC target and first Ag target start to sputter with same condition as (5) process, meanwhile starting a second Ag target, with the current density of the second Ag target being 0.4 A, and the chamber temperature of 40° C., according to the moving-ahead direction of the film, arranging the P-type Si target, the TiC target, the first Ag target and the second Ag target in sequence and concurrently sputtering them to form a second antimicrobial layer containing Si, TiC, first Ag and second Ag on the surface of the film, winding the other end of the film on the second reel at the same time;

(7) completing coating: first turning off the P-type Si target and the TiC target, then turning off the first Ag target and the second Ag target, then cutting off all the gases, and stopping the rolling mechansim, after chamber cooling down by itself for 10 minutes, ventilating the vacuum chamber to atmospheric pressure section by section, and taking out the workpiece to complete coating.

### EXAMPLE 4

A winding coating method of an antimicrobial plastic film, comprising the following steps:

(1) pretreatment: installing reels and a film on a shelf, putting them into a vacuum chamber, then starting to wind the film on one reel and unwind the film off another reel, performing corona treatment;

(2) vacuum treatment: evacuating the vacuum chamber to 1×10-3 Pa;

(3) applying a bonding layer: turning on the mid-frequency power supply and adjusting it to 30V with a duty ratio of 20%-30%, and passing argon until the vacuum degree reaches 2.0×10-2 Pa, starting to sputter on P-type Si target, with the current density of the P-type Si target being 6 A and the chamber temperature adjusted to 40° C., and then staring to reel the film at the linear speed of the film being 0.1-0.3 m/s, sputtering the P-type Si target towards the moving-ahead direction of the film to form a Si bonding film on the surface of the film, the film coated with the Si bonding layer continuing to move ahead into the next coating process;

(4) applying a carrier layer: concurrently sputtering the P-type Si target and a TiC target by using mid-frequency power supply, with the current density of the TiC target being 6 A, and the chamber temperature of 40° C., according to the moving-ahead direction of the film, arranging the P-type Si target and the TiC target in sequence and concurrently sputtering them to form a carrier layer containing Si and TiC on the surface of the film, the film coated with the carrier layer containing Si and TiC continuing to move ahead into the next coating process;

(5) applying a first antimicrobial layer: holding the P-type Si target and the TiC target, meanwhile starting a first Ag target, by using DC power supply with the current density of the first Ag target being 0.4 A, and the chamber temperature of 40° C., according to the moving-ahead direction of the film, arranging the P-type Si target, the TiC target and the first Ag target in sequence and concurrently sputtering them to form a first antimicrobial layer containing Si, TiC and Ag on the surface of the film, the film coated with the first antimicrobial layer containing Si, TiC and Ag continuing to move ahead into the next coating process;

(6) applying a second antimicrobial layer: another set of P-type Si target, TiC target and first Ag target start to sputter with same condition as (5) process, meanwhile starting a second Ag target, with the current density of the second Ag target being 0.4 A, and the chamber temperature of 40° C., according to the moving-ahead direction of the film, arranging the P-type Si target, the TiC target, the first Ag target and the second Ag target in sequence and concurrently sputtering them to form a second antimicrobial layer containing Si, TiC, first Ag and second Ag on the surface of the film, winding the other end of the film on the second reel at the same time;

(7) completing coating: first turning off the P-type Si target and the TiC target, then turning off the first Ag target and the second Ag target, then cutting off all the gases, and stopping the rolling mechansim, after chamber cooling down by itself for 10 minutes, ventilating the vacuum chamber to atmospheric pressure section by section, and taking out the workpiece to complete coating.

### EXAMPLE 5

A winding coating method of an antimicrobial plastic film, comprising the following steps:

(1) pretreatment: installing reels and a film on a shelf, putting them into a vacuum chamber, then starting to wind the film on one reel and unwind the film off another reel, performing corona treatment;

(2) vacuum treatment: evacuating the vacuum chamber to 1×10-3 Pa;

(3) applying a bonding layer: turning on the mid-frequency power supply and adjusting it to 40V with a duty ratio of 20%-30%, and passing argon until the vacuum degree reaches 2.0×10-2 Pa, starting to sputter on P-type Si target, with the current density of the P-type Si target being 6 A and the chamber temperature adjusted to 40° C., and then staring to reel the film at the linear speed of the film being 0.1-0.3 m/s, sputtering the P-type Si target towards the moving-ahead direction of the film to form a Si bonding film on the surface of the film, the film coated with the Si bonding layer continuing to move ahead into the next coating process;

(4) applying a carrier layer: concurrently sputtering the P-type Si target and a TiC target by using mid-frequency power supply, with the current density of the TiC target being 6 A, and the chamber temperature of 40° C., according to the moving-ahead direction of the film, arranging the P-type Si target and the TiC target in sequence and concurrently sputtering them to form a carrier layer containing Si and TiC on the surface of the film, the film coated with the carrier layer containing Si and TiC continuing to move ahead into the next coating process;

(5) applying a first antimicrobial layer: holding the P-type Si target and the TiC target, meanwhile starting a first Ag target, by using DC power supply with the current density of the first Ag target being 0.4 A, and the chamber temperature of 40° C., according to the moving-ahead direction of the film, arranging the P-type Si target, the TiC target and the first Ag target in sequence and concurrently sputtering them to form a first antimicrobial layer containing Si, TiC and Ag on the surface of the film, the film coated with the first antimicrobial layer containing Si, TiC and Ag continuing to move ahead into the next coating process;

(6) applying a second antimicrobial layer: another set of P-type Si target, TiC target and first Ag target start to sputter with same condition as (5) process, meanwhile starting a second Ag target, with the current density of the second Ag target being 0.4 A, and the chamber temperature of 40° C., according to the moving-ahead direction of the film, arranging the P-type Si target, the TiC target, the first Ag target and the second Ag target in sequence and concurrently sputtering them to form a second antimicrobial layer containing Si, TiC, first Ag and second Ag on the surface of the film, winding the other end of the film on the second reel at the same time;

(7) completing coating: first turning off the P-type Si target and the TiC target, then turning off the first Ag target and the second Ag target, then cutting off all the gases, and stopping the rolling mechansim, after chamber cooling down by itself for 5 minutes, ventilating the vacuum chamber to atmospheric pressure section by section, and taking out the workpiece to complete coating.

### EXAMPLE 6

The experimental data is measured on the interlaminar bonding force of the antimicrobial plastic film obtained in Examples 1-5, and the results are shown in the following table:

| Example | 1 | 2 | 3 | 4 | 5 |
|---|---|---|---|---|---|
| Bonding force(N) | 60.5 | 62 | 63.5 | 65 | 67 |

It can be seen from the experimental results that the interlaminar bonding force of the antimicrobial coating on the surface of the plastic film obtained by this technical solution is greater than 60N, which means that the interlaminar bonding force is better and can meet the requirements of ordinary film products.

### EXAMPLE 7

The plastic films in Examples 1-5 are all plastic films with the same material. We take the commonly-used plastic films with the material as same as those in Examples 1-5 as a control group, after measuring six groups of samples for 5 hours and 10 hours under the same use environment, respectively, we count the number of bacterial colonies on the their surface, then show the results in the following table:

| Experimental | Example | Example | Example | Example | Example | control |
|---|---|---|---|---|---|---|
| sample | 1 | 2 | 3 | 4 | 5 | group |
| 5 hours | 9 | 11 | 14 | 10 | 7 | 45 |
| (colonies/cm²) | | | | | | |
| 10 hours | 4 | 5 | 6 | 4 | 3 | 56 |
| (colonies/cm²) | | | | | | |
| 24 hours | 0 | 0 | 0 | 0 | 0 | 72 |
| (colonies/cm²) | | | | | | |

It can be seen from the experimental results that compared with ordinary plastic films the plastic film with the antimicrobial coating formed by adopting this technical solution has remarkable sterilization effect, and is very valuable in application.

The above examples are described in detail only for specific description to a feasible embodiment of the present invention, without any limitations on the protection scope of the present invention. Any equivalent implementation or modification that does not depart from the technical spirit of the present invention shall fall within the patent scope of the present application.

1. An antimicrobial plastic film comprising a plastic film main part (1), wherein a surface of said plastic film main part (1) is coated with an antimicrobial coating (2), said antimicrobial coating (2) further comprising a bonding layer (21), a carrier layer (22), a first antimicrobial layer (23) and a second antimicrobial layer (24).

2. The antimicrobial plastic film according to claim 1, wherein the plastic film main part (1) further comprising at least one of PET, TPU, EVA, PU, PP, PVC, PE, PO, ABS, PC, POM, PA, TPE and silica gel.

3. The antimicrobial plastic film according to claim 1, wherein said antimicrobial coating (2) covers an outer surface of said plastic film main part (1).

4. The antimicrobial plastic film according to claim 1, wherein said antimicrobial coating (2) covers an inner surface of said plastic film main part (1).

5. The antimicrobial plastic film according to claim 1, wherein said bonding layer (21) further comprising a layer made from Si.

6. The antimicrobial plastic film according to claim 1, wherein said carrier layer (22) further comprising a layer made from Si and TiC.

7. The antimicrobial plastic film according to claim 1, wherein said first antimicrobial layer (23) further comprising a layer made from Si, TiC and Ag.

8. The antimicrobial plastic film according to claim 1, wherein said second antimicrobial layer (24) further comprising a layer made from Si, TiC, a first Ag and a second Ag.

9. A winding coating method for a antimicrobial plastic film, comprising the following steps:
(1) pretreatment: installing two reels and a film on a shelf, placing the reels, the film and the shelf into a vacuum chamber, then starting to wind the film on one reel and unwind the film off another reel, performing corona treatment;
(2) vacuum treatment: evacuating said vacuum chamber to 1×10-3 Pa;
(3) applying a bonding layer: turning on a mid-frequency power supply and adjusting it to 30-40V with a duty ratio of 20%-30%, and passing argon until the vacuum reaches 2.0×10-2 Pa, starting sputter on P-type Si target, with current density of said P-type Si target being 6 A and the chamber temperature adjusted to 40° C., and then starting to reel the film at the linear speed of 0.1-0.3 m/s, sputtering said P-type Si target towards moving-ahead direction of the film to form a Si bonding film on the surface of the film;
(4) applying a carrier layer: concurrently sputtering said P-type Si target and a TiC target using a mid-frequency power supply, wherein the current density of said TiC target is 6 A, and the chamber temperature is 40° C., wherein, arranging said P-type Si target and said TiC target in sequence in the moving direction of the film and concurrently sputtering them to form a carrier layer containing Si and TiC on surface of the film;
(5) applying a first antimicrobial layer: holding said P-type Si target and said TiC target, starting a first Ag target, with a current density of 0.4 A, and a chamber temperature of 40° C., arranging said P-type Si target, said TiC target and said first Ag target in sequence in the moving direction of the film and concurrently sputtering them to form a first antimicrobial layer containing Si, TiC and Ag on the surface of the film;
(6) applying a second antimicrobial layer: start sputtering another set of P-type Si target, TiC target and first Ag target with same condition as (5) process, starting a second Ag target, with a current density of 0.4 A, and achamber temperature of 40° C., arranging said P-type Si target, said TiC target, said first Ag target and said second Ag target in sequence in the moving direction of the film, and concurrently sputtering them to form a second antimicrobial layer containing Si, TiC, first Ag and second Ag on the surface of the film, winding one end of the film on the second reel at the same time;
(7) completing coating: turning off said P-type Si target and said TiC target, turning off said first Ag target and said second Ag target, cutting off all gases, stopping winding the reel after chamber cooling down by itself for 5-10 minutes, ventilating said vacuum chamber to atmospheric pressure.
